(19) United States
(12) Patent Application Publication
(10) Pub. No.: US 2026/0095196 A1
(43) Pub. Date: Apr. 2, 2026

(54) TIME SERIES DATA COMPRESSION

(71) Applicant: TERADATA US, INC., San Diego, CA (US)

(72) Inventor: Denis Pierre Molin, Draveil (FR)

(21) Appl. No.: 18/901,276

(22) Filed: Sep. 30, 2024

(51) Int. Cl. H03M 7/30; G06F 17/40

(52) U.S. Cl. CPC H03M 7/6011; G06F 17/40

(57) ABSTRACT

In some examples, a system compresses a data time series by initializing an intermediate data time series by adding a first data point and a second data point to the intermediate data time series, and performing a compression processing loop. In a respective round of a plurality of rounds of the compression processing loop, the system selects a data point to extract from the data time series, the data point selected based on a comparison of distances between a line segment connecting data points in the intermediate data time series and corresponding data points of the data time series, and the system adds the extracted data point to the intermediate data time series. The system outputs the intermediate data time series produced by the compression processing loop as a compressed data time series.

### BACKGROUND

Data processing can be applied on input data for various purposes. In some cases, the input data can be in the form of a time series of data. The time series of data includes data points at successive time points.

### BRIEF DESCRIPTION OF THE DRAWINGS

Some implementations of the present disclosure are described with respect to the following figures.

FIG. 1 is a block diagram of an arrangement including a computer system for performing data time series compression, according to some examples.

FIG. 2A to FIG. 2E are graphs illustrating extracted data points that are included in an intermediate data time series produced by rounds of a compression processing loop, according to some examples.

FIG. 3 is a flow diagram of a process according to some examples.

FIG. 4 is a block diagram of a system according to some examples.

Throughout the drawings, identical reference numbers designate similar, but not necessarily identical, elements. The figures are not necessarily to scale, and the size of some parts may be exaggerated to more clearly illustrate the example shown. Moreover, the drawings provide examples and/or implementations consistent with the description; however, the description is not limited to the examples and/or implementations provided in the drawings.

### DETAILED DESCRIPTION

A time series of data (or equivalently, a “data time series”) can be a long data time series that has a large quantity of data points, e.g., on the order of millions, billions, trillions, or even more data points. The long data time series can represent one or more attributes of a database or another data store.

Compression of an original data time series (such as a long data time series) can be performed to generate a compressed data time series that includes a reduced quantity of data points as compared to the original data time series. Generally, some example compression techniques apply fitting or smoothing to actual data points in an original data time series to generate a compressed data time series. For example, a fitting can include polynomial fitting, while smoothing can be performed using wavelet compression or Fourier transform-based compression. The compressed data time series produced by the foregoing example compression techniques include approximate data points produced by the fitting or smoothing, where the approximate data points provide an approximate representation of the actual data points in the original data time series. For example, a fitted polynomial produced by polynomial fitting representing approximate data points may not pass through actual data points of the original data time series. The foregoing example compression techniques do not attempt to keep actual data points of the original data time series; rather, such compression techniques seek to approximate the original data time series as closely as possible with approximate data points. Although some of the approximate data points may coincidentally have the same values as actual data points of the original data time series, that does not change the fact that the goal of the foregoing example compression techniques is not to keep the actual data points.

Additionally, because the foregoing example compression techniques may apply complex computations, the processing time for compressing data can be relatively long. Such compression techniques also do not scale well with increasing time series lengths. As the length of an original data time series increases, the processing time to compress the original data time series increases at least proportionally; in some cases, the processing time can increase on the order of n* log (n) or n² with certain compression algorithms, where n represents the length of the original data time series. As a result, a requester (e.g., a user, a program, or a machine) that submitted a request to perform an operation that includes compressing an original data time series may have to wait a long time to obtain a result of the operation.

In accordance with some implementations of the present disclosure, compression systems or techniques apply compression of an original data time series by selecting actual data points from the original data time series to include in a compressed data time series. Except possibly for initial data points used to initially populate an intermediate data time series (that would ultimately become the compressed data time series after completion of a compression processing loop), all remaining data points added to the intermediate data time series are actual data points extracted from the original data time series. The compression according to some implementations of the present disclosure effectively selects a subset of actual data points of the original data time series to use in the compressed data time series.

Compression systems or techniques according to some examples of the present disclosure improve computer functionality and the relevant technology of data reduction so that more efficient use of storage resources and faster processing times can be achieved when performing data analytics. A smaller amount of high-speed storage can be used to store the compressed data time series, which includes actual data points from the original data time series for an improved representation of the original data time series.

The compression according to some examples of the present disclosure includes initializing an intermediate data time series (that ultimately will become a compressed data time series) by adding a first data point and a second data point to the intermediate data time series. After the initializing, the compression performs one or more rounds of the compression processing loop, where each round includes multiple iterations. In each round, the compression processing loop selects a data point to extract from the original data time series, and adds the extracted data point to the intermediate data time series. The data point selected is based on a comparison of distances between a line segment connecting data points in the intermediate data time series and corresponding data points of the original data time series. The compression processing loop is a nested loop including an outer loop and an inner loop, in which the outer loop includes rounds with each round selecting a data point to add to the intermediate data time series, and the inner loop is performed within a round and iterates through one or more line segments defined by the data points in the intermediate data time series to find a data point with the largest distance to the line segment(s). After completion of the compression processing loop, the intermediate data time series produced by the compression processing loop is output as a compressed data time series.

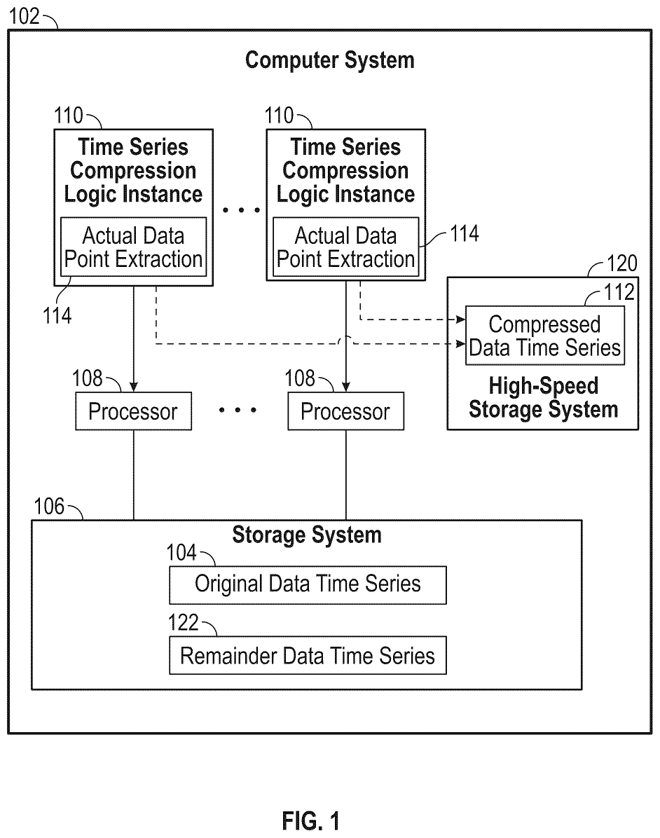

FIG. 1 is a block diagram of a computer system 102 that includes time series compression logic for performing compression of an original data time series 104 according to some examples of the present disclosure. The computer system 102 can be implemented using one or more computers. The original data time series 104 is stored in a storage system 106, which may be part of the computer system 102 or separate from the computer system 102. In some cases, the storage system 106 can be a distributed storage system with multiple data stores distributed over a wide area at different locations. In such examples, the original data time series 104 can be distributed across the data stores.

The computer system 102 includes hardware processors 108, which may execute respective time series compression logic instances 110 in parallel. The time series compression logic can be implemented using a program, and the time series compression logic instances 110 are multiple invoked instances of the program.

When performing time series compression according to some examples of the present disclosure, the multiple time series compression logic instances 110 can process, in parallel, different portions of an intermediate data time series in multiple rounds of a compression processing loop. The ability to process portions of the intermediate data time series in parallel increases the throughput (and reduces the amount of time taken) to perform compression of the original data time series 104.

In other examples, parallel processing is not performed in the compression processing loop. In such examples, just one time series compression logic instance 110 is executed on a hardware processor 108 to compress the original data time series 104.

In accordance with some examples of the present disclosure, each time series compression logic instance 110 performs actual data point extraction 114 as part of selecting data points for inclusion in a compressed data time series 112. The actual data point extraction 114 refers to selecting an actual data point of the original data time series 104 to include in the compressed data time series 112. Such selected actual data points are not subject to fitting or smoothing for producing approximate data points to use as a compressed representation of the actual data points.

The result of the compression of the original data time series 104 is the compressed data time series 112. In some examples, the compressed data time series 112 can be stored in a high-speed storage system 120. The high-speed storage system 120 can be implemented with storage device(s) with higher access speeds than storage device(s) of the storage system 106. For example, the high-speed storage system 120 can be implemented with one or more flash memory devices or other types of memory devices, and the storage system 106 can be implemented with one or more disk-based storage devices.

The high-speed storage system 120 may be part of the computer system 102, or alternatively, the high-speed storage system 120 may be part of an analytics system (not shown) that is to apply analytics on the compressed data time series 112. In the latter examples, the computer system 102 can transfer the compressed data time series 112 over a network (not shown) to the analytics system. Analytics performed on the compressed data time series 112 stored in the high-speed storage system 120 can be completed with lower latency than if the compressed data time series 112 were stored in the slower storage system 106.

The analytics applied by the analytics system can include generating a visualization of the compressed data time series 112 to represent the original data time series 104 to a user or another entity (a program or a machine). The analytics system can also apply to other analytics on the compressed data time series 112. An example of such other analytics can include anomaly detection to identify anomalies in the original data time series 104. An anomaly can refer to data points of the original data time series 104 that do not have expected values, such as outlier values. Another anomaly can refer to data points that are densely populated in time so that a pixel of the visualization would have to represent a much larger quantity of data points than another pixel of the visualization. In further examples, the analytics system can apply plateau detection to detect long spans between consecutive sub-samples of data points exhibiting low slope in absolute value. As additional examples, the analytics system can perform peak or step detection, to identify short spans with large variations up and down.

In some examples, in addition to generating the compressed data time series 112 that includes a subset (less than all) of data points of the original data time series 104, the time series compression logic instances 110 can also generate a remainder data time series 122 that includes remainder data points of the original data time series 104. The remainder data points include those data points of the original data time series 104 not selected for inclusion in the compressed data time series 112. The remainder data time series 122 can be written to the storage system 106.

In alternative examples, the remainder data time series 122 is not generated by the time series compression logic instances 110.

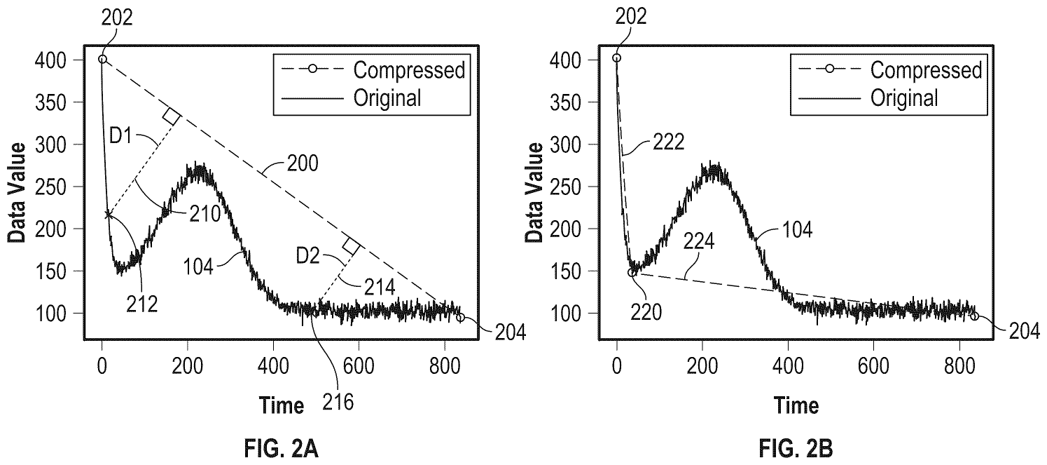

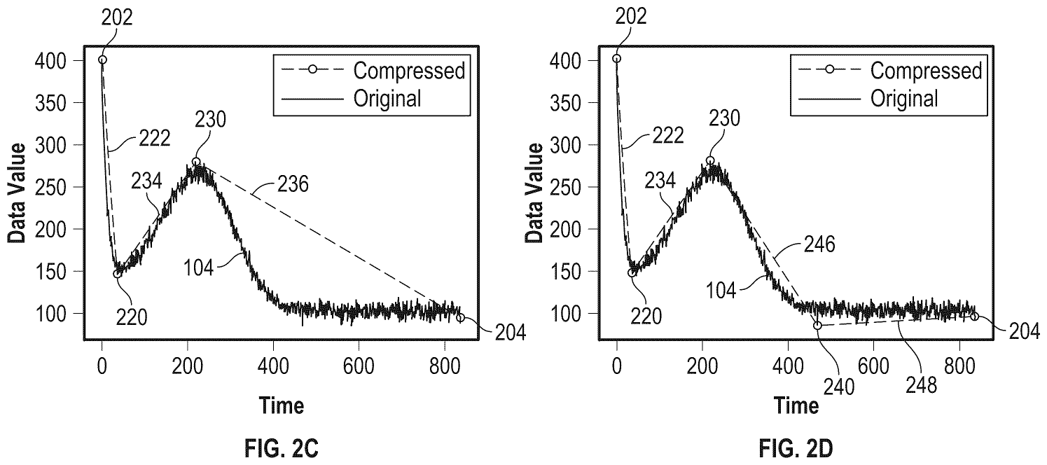

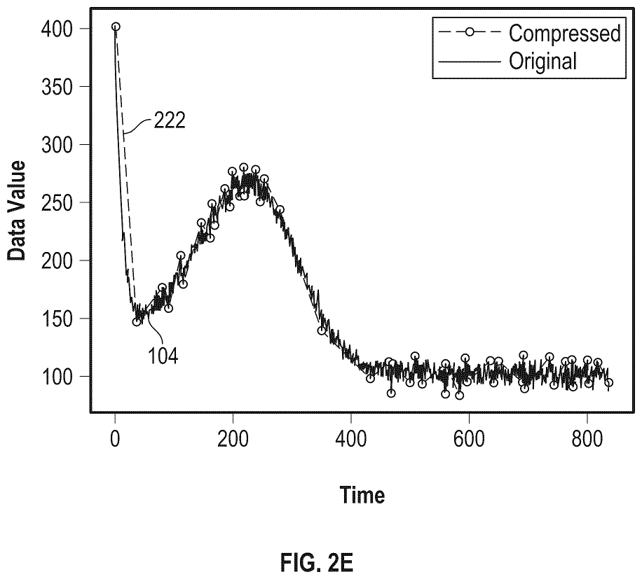

An example of a compression processing loop as performed by a time series compression logic instance 110 according to some examples of the present disclosure is discussed below in connection with FIGS. 2A-2E, which are graphs showing actual data points of the original data time series 104 and extracted data points to be included in the compressed data time series 112. The compression processing loop represented by FIGS. 2A-2E includes multiple rounds (outer loop), and each round includes plural iterations (inner loop).

In each graph, the horizontal axis represents time (tᵢ), while the vertical axis represents data values (sᵢ) of data points, and i=1, . . . , n, with n representing the quantity of data points in the original data time series 104. In FIG. 2A, the time series compression logic instance 110 initializes an intermediate data time series (represented by a line segment 200) by adding a first data point and a second data point to the intermediate data time series. In some examples, the first data point is the starting data point 202 of the original data time series 104, and the second data point is the ending data point 204 of the original data time series 104. In such examples, the starting data point 202 and the ending data point 204 are actual data points of the original data time series 104.

In other examples, instead of initializing the intermediate data time series with the starting data point 202 and the ending data point 204 of the original data time series 104, the first data point and/or the second data point used to initialize the intermediate data time series can be a derived data point. For example, the first data point can be calculated based on aggregating (e.g., averaging, taking the median, etc.) a first collection of data points at the beginning of the original data time series 104. Additionally, or alternatively, the second data point can be calculated based on aggregating (e.g., averaging, taking the median, etc.) a second collection of data points at the end of the original data time series 104. In further examples, the first and second data points may be other derived values.

After the initialization depicted in FIG. 2A, the intermediate data time series includes two data points 202 and 204. In other examples, the intermediate data time series can be initialized with more than two data points.

In the ensuing discussion, the original data time series 104 is represented as

$$s = {\{ ( {t}_{i} , {s}_{i} ) \}}_{i = 1 , … , n} ,$$

where n represents the quantity of data points in s.

An intermediate data time series is represented as s_{new}. As a result of the initialization, the intermediate data time series, s_{new}, includes the beginning and ending data points.

$${s}_{n e w} := {\{ ( {t}_{i}^{′} , {s}_{i}^{′} ) \}}_{i = 1 , 2} , where {t}_{1}^{′} = {t}_{1} , {s}_{1}^{′} = {s}_{1} , {t}_{2}^{′} = {t}_{n} , and {s}_{2}^{′} = {s}_{n} .$$

The data point 202 is

$$( {t}_{1}^{′} , {s}_{1}^{′} ) ,$$

data point 204 is

$$( {t}_{2}^{′} , {s}_{2}^{′} ) .$$

In some examples, when a data point of the original data time series, s, is extracted for inclusion in the intermediate data time series, s_{new}, the data point is removed from the original data time series, s. Thus, after the initialization phase, the remainder data time series, sᵣₑₘ, includes:

$${s}_{r e m} := {\{ ( {t}_{i} , {s}_{i} ) \}}_{i = 2 , … , n - 1} .$$

After the initialization phase, the compression processing loop performs multiple rounds (outer loop), starting with a first round that iterates a variable k from 1 to Length(s_{new})−1 (inner loop), where Length(s_{new}) is the length of the intermediate data time series, s_{new}. The inner loop iterates through one or more line segments defined by the data points of the intermediate data time series. In the first round after the initialization, there is just a single line segment 200 as shown in FIG. 2A.

In iteration k of the first round of the compression processing loop, the compression processing loop derives the following line segment, seg, based on data points in the intermediate data time series, s_{new}:

$$s eg := \{ ( {t}_{k}^{′} , {s}_{k}^{′} ) , ( {t}_{k + 1}^{′} , {s}_{k + 1}^{′} ) \} .$$

The line segment, seg, is defined between two data points:

$$( {t}_{k}^{′} , {s}_{k}^{′} ) , ( {t}_{k + 1}^{′} , {s}_{k + 1}^{′} ) .$$

In FIG. 2A, the two data points are 202 and 204. Since there are just two data points (i.e., Length(s_{new})=2) in the intermediate data time series, s_{new}, iterating the variable k from 1 to Length(s_{new})−1 means there is just one iteration in the first round. The line segment in the first round is represented as

$$\{ ( {t}_{1}^{′} , {s}_{1}^{′} ) , ( {t}_{2}^{′} , {s}_{2}^{′} ) \} .$$

The coefficients of the line segment, seg, are computed as follows:

$$a = 1 ,$$

$$b = - \frac{{s}_{k + 1} - {s}_{k}}{{t}_{k + 1} - {t}_{k}} ,$$

$$c = - a \cdot {s}_{k} - b \cdot {t}_{k} .$$

The line segment, seg, (200 in FIG. 2A) is represented as:

$$a \cdot s + b \cdot t + c = 0 for t ∈ [ {t}_{k}^{′} , {t}_{k + 1}^{′} ] .$$

In iteration k, the compression processing loop computes the distances between the line segment, seg, and all data points (tᵢ, sᵢ) (tᵢ being between

$${t}_{k}^{′} and {t}_{k + 1}^{′} )$$

of the remainder data time series, sᵣₑₘ (which excludes the removed data points 202 and 204). The distances for iteration k are included in a distance vector, distanceₖ, computed as follows:

$${distance}_{k} = {\{ \vert \frac{a \cdot {s}_{p} + b \cdot {t}_{p} + c}{\sqrt{{a}^{2} + {b}^{2}}} \vert \}}_{p = \{ p \vert {t}_{p} ∈ ] {t}_{k}^{′} , {t}_{k + 1}^{′} [ \}} .$$

The time points tₚ at which the distances in the distance vector, distanceₖ, are computed include time points between tₖ and tₖ₊₁, but excluding tₖ and tₖ₊₁, as represented by

$$] {t}_{k}^{′} , {t}_{k + 1}^{′} [$$

in the equation above. In the first round, the distances are computed from the line segment

$$\{ ( {t}_{1}^{′} , {s}_{1}^{′} ) , ( {t}_{2}^{′} , {s}_{2}^{′} ) \}$$

to the data points

$${\{ ( {t}_{i} , {s}_{i} ) \}}_{i ∈ ] {t}_{1}^{′} , {t}_{2}^{′} [} .$$

Each distance from the line segment, seg, to a given data point (tᵢ, sᵢ) is along an axis that is perpendicular to the line segment, seg. For example, in FIG. 2A, a distance D1 between the line segment 200 and a data point 212 of the remainder data time series is along an axis 210 that is perpendicular to the line segment 200, and a distance D2 between the line segment 200 and a data point 216 of the remainder data time series is along an axis 214 that is perpendicular to the line segment 200. Distances between the line segment 200 and other data points of the remainder data time series are similarly computed.

In other examples, a Chebychev distance can be computed between a line segment and data points of the remainder data time series.

After proceeding through the one iteration of the first round of the compression processing loop based on incrementing the variable k from 1 to Length(s_{new})−1, the output of the Length(s_{new})−1 iterations is:

$${\{ {distance}_{k} \}}_{k = 1 , ... , Length ( {s}_{new} ) - 1} .$$

There are Length(s_{new})−1 distance vectors {distanceₖ} (k=1, . . . , Length(s_{new})−1) computed by the compression processing loop. In the first round, there is just one distance vector since there is one line segment. The time series compression logic instance 110 compares the distances in the distance vectors {distanceₖ}, and the time series compression logic instance 110 identifies the maximum distance Dmax in the distance vectors {distanceₖ}.

The maximum distance Dmax is between the line segment, seg, and a given data point (tᵢ₋ₘₐₓ, sᵢ₋ₘₐₓ) of the remainder data time series, where tᵢ₋ₘₐₓ is a time point between

$${t}_{k}^{′} and {t}_{k + 1}^{′} .$$

This given data point (tᵢ₋ₘₐₓ, sᵢ₋ₘₐₓ) is a candidate to add to the intermediate data time series.

Before adding the given data point (tᵢ₋ₘₐₓ, sᵢ₋ₘₐₓ) to the intermediate data time series, the time series compression logic instance 110 checks if a stopping criterion for the compression processing loop is satisfied. In a first example, the stopping criterion is satisfied if Dmax is less than a distance threshold. Dmax being less than the distance threshold indicates that line segments connecting the data points in the intermediate data time series are relatively close in distance (less than the distance threshold) to the data points of the original data time series 104. Thus, once Dmax drops below the distance threshold, that indicates the compression processing loop has produced a sufficiently close representation of the original data time series 104. The distance threshold can by dynamically tunable for different use cases.

In a second example, the stopping criterion is satisfied if a quantity of data points in the intermediate data time series exceeds a quantity threshold. For example, the quantity threshold can correspond to a number of pixels to be used in a visualization. A goal of the visualization is to represent one data point per pixel (or some specified number of data points per pixel).

In other examples, other stopping criteria can be used.

If the stopping criterion is satisfied, the time series compression logic instance 110 stops the compression processing loop, and the intermediate data time series produced so far is output as the compressed data time series.

However, if the stopping criterion is not satisfied, the time series compression logic instance 110 proceeds further with the second round of the compression processing loop. In the second round, the compression processing loop adds the given data point (tᵢ₋ₘₐₓ, sᵢ₋ₘₐₓ) from the remainder data time series corresponding to Dmax to the intermediate data time series. In FIG. 2B, the added given data point is data point 220 from the original data time series 104. Thus, in FIG. 2B, the intermediate data time series has three data points 202, 220, and 204, which are respectively represented as

$$( {t}_{1}^{′} , {s}_{1}^{′} ) , {t}_{3}^{′} , {s}_{3}^{′} ) , and ( {t}_{2}^{′} , {s}_{2}^{′} ) .$$

The data point 220 added to the intermediate data time series is removed from the remainder data time series. In the second round, the remainder data time series includes the data points of the original data time series 104 except the data points 202, 220, and 224.

In the second round, the compression processing loop iterates the variable k from 1 to Length(s_{new})−1 (in the second round Length(s_{new})−1 is equal 2). Because there are three data points in the intermediate data time series of FIG. 2B, two line segments 222 and 224 are defined, where the line segment 222 is between the data points 202 and 220, and the line segment 224 is between the data points 220 and 204. The two iterations (iteration 1 and iteration 2) of the second round can involve independent computations that can be performed in parallel, such as by different time series compression logic instances 110. Generally, if there are k iterations, the computations of the k iterations may be performed by k time series compression logic instances 110 in parallel.

In iteration 1 of the second round of the compression processing loop, the compression processing loop derives the line segment 222 based on the following data points in the intermediate data time series, s_{new}:

$$seg ( 222 ) := \{ ( {t}_{1}^{′} , {s}_{1}^{′} ) , ( {t}_{3}^{′} , {s}_{3}^{′} ) \} .$$

The data point

$$( {t}_{1}^{′} , {s}_{1}^{′} )$$

is 202 in FIG. 2B, and the data point

$$( {t}_{3}^{′} , {s}_{3}^{′} )$$

### is 220 in FIG. 2B.

In iteration 2 of the second round of the compression processing loop, the compression processing loop derives the line segment 224 based on the following data points in the intermediate data time series, s_{new}:

$$seg ( 224 ) := \{ ( {t}_{3}^{′} , {s}_{3}^{′} ) , ( {t}_{2}^{′} , {s}_{2}^{′} ) \} .$$

The data point

$$( {t}_{3}^{′} , {s}_{3}^{′} )$$

is 220 in FIG. 2B, and the data point

$$( {t}_{2}^{′} , {s}_{2}^{′} )$$

### is 204 in FIG. 2B.

In iteration 1 of the second round, the compression processing loop calculates distances between the line segment 222 and data points

$${\{ ( {t}_{i} , {s}_{i} ) \}}_{i ∈ ] {t}_{1}^{′} , {t}_{3}^{′} [} .$$

In iteration 2 of the second round, the compression processing loop calculates distances between the line segment 224 and data points

$${\{ ( {t}_{i} , {s}_{i} ) \}}_{i ∈ ] {t}_{3}^{′} , {t}_{2}^{′} [} .$$

The maximum distance of the distances calculated in iterations 1 and 2 of the second round corresponds to a given data point that is a candidate to add to the intermediate data time series. Before adding the given data point to the intermediate data time series, the time series compression logic instance 110 determines if the stopping criterion is satisfied. If not, the time series compression logic instance 110 proceeds to the third round of the compression processing loop, in which a data point 230 is added to the intermediate data time series, as shown in FIG. 2C. The data point 230 is also removed from the remainder data time series. In the third round, the intermediate data time series includes four data points 202, 220, 230, and 204. Three line segments 222, 234, and 236 are defined in the third round, and the compression processing loop calculates distances between each of the line segments 222, 234, and 236 and corresponding data points of the remainder data time series. Note that in the third round, the line segment 222 is the same as the line segment 222 in the second round.

The maximum distance is identified between the line segments 222, 234, and 236 and the data points of the original data time series 104.

FIG. 2D shows the fourth round of the compression processing loop, in which another data point 240 from the original data time series 104 has been added to the intermediate data time series. The data point 240 is also removed from the remainder data time series. In the fourth round, the intermediate data time series includes five data points 202, 220, 230, 240, and 204. Four line segments 222, 234, 246, and 248 are defined between the five data points. In the fourth round, the compression processing loop identifies the maximum distance between the line segments 222, 234, 246, and 248 and corresponding data points of the remainder data time series. Note that in the fourth round, the line segments 222 and 234 are the same as the line segments 222 and 234 in the third round.

The compression processing loop continues through additional rounds until the intermediate data time series includes the data points shown in FIG. 2E. In the example, it is assumed that the stopping criterion is reached in the round of the compression processing loop represented by FIG. 2E.

In further examples, the compression processing loop can include refinements to improve performance or accuracy. For example, the distance threshold used as part of the stopping criterion can be set equal to 1. To allow use of such a distance threshold, the data points (tᵢ, sᵢ) of the original data time series, s, can be normalized, by dividing s; by a tolerance value, s_tol, and dividing tᵢ by a tolerance value, t_tol. The effect of normalizing the data points is that the distance between a line segment, seg, and the normalized data points of the normalized original time series will have the following characteristic: the distance along the time axis between the line segment, seg, and a given normalized data point is less than t_tol, and the distance along the data value axis between the line segment, seg, and the given normalized data point is less than s_tol. Such smaller distance values allows computations to be more efficient since the compression processing loop is using smaller values.

Further, parallel processing can be performed on different line segments in each round of the compression processing loop. For example, for FIG. 2B (the second round), a first time series compression logic instance 110 can perform the distance calculations from the line segment 222, and a different second time series compression logic instance 110 can perform the distance calculations from the line segment 224. Similarly, for FIG. 2D (the fourth round), a first time series compression logic instance 110 can perform the distance calculations from the line segment 242, a second time series compression logic instance 110 can perform the distance calculations from the line segment 244, a third time series compression logic instance 110 can perform the distance calculations from the line segment 246, and a fourth time series compression logic instance 110 can perform the distance calculations from the line segment 248.

In addition, once it is determined that distances between a particular line segment and corresponding data points of the original data time series 104 are all less than the distance threshold, then the particular line segment can be removed from consideration in a subsequent round of the compression processing loop. For example, if it is determined in the second round that all distances between the line segment 222 (FIG. 2B) and the corresponding data points of the original data time series 104 are less than the distance threshold, then the line segment 222 (and the corresponding data points of the original data time series 104) can be removed from consideration in subsequent rounds of the compression processing loop for better efficiency.

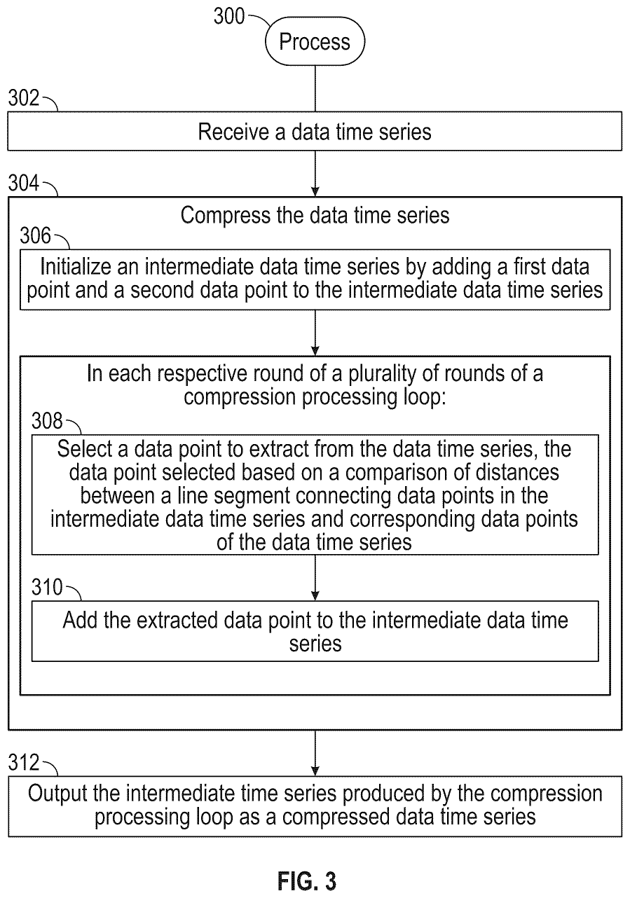

FIG. 3 is a flow diagram of a process 300 according to some examples of the present disclosure. The process 300 can be performed by one or more time series compression logic instances (e.g., 110 in FIG. 1) in a system.

The process 300 includes receiving (at 302) a data time series. The process 300 includes compressing (at 304) the data time series, where the compressing includes tasks 306, 308, and 310. Task 306 includes initializing an intermediate data time series by adding a first data point and a second data point to the intermediate data time series (e.g., as shown in FIG. 2A).

Tasks 308 and 310 are performed in each respective round of a plurality of rounds (outer loop) of a compression processing loop. Task 308 includes selecting a data point to extract from the data time series, the data point selected based on a comparison of distances (computed in one or more iterations of the inner loop within the respective round) between a line segment connecting data points in the intermediate data time series and corresponding data points of the data time series. Task 310 includes adding the extracted data point to the intermediate data time series.

The process 300 includes outputting (at 312) the intermediate data time series produced by the compression processing loop as a compressed data time series.

In some examples, the selecting of the data point includes selecting the data point having a largest distance to the line segment.

In some examples, in the respective round, identifying the line segment and calculating the distances between the line segment and the corresponding data points of the data time series. The line segment is identified based on connecting two successive data points in the intermediate data time series.

In some examples, a distance between the line segment and a given data point of the data time series is along an axis that is perpendicular to the line segment.

In some examples, a distance between the line segment and a given data point of the data time series is a Chebychev distance.

In some examples, the line segment is a first line segment, and wherein in the respective round, the system identifies a second line segment different from the first line segment, where the second line segment connects further data points in the intermediate data time series. The system calculates distances between the second line segment and further corresponding data points of the data time series.

In some examples, the selecting of the data point to extract from the data time series is based on a comparison of first distances between the first line segment and the corresponding data points of the data time series, and second distances between the second line segment and the further corresponding data points of the data time series.

In some examples, the selecting of the data point includes selecting the data point having the largest distance of the first distances and the second distances.

In some examples, the system determines whether all distances of a given line segment of the first line segment and the second line segment is less than a distance threshold. Based on determining that all distances of the given line segment is less than the distance threshold, the system excludes the given line segment from consideration in a next round of the plurality of rounds.

In some examples, in the compression processing loop, the system determines whether a stopping criterion is satisfied. In response to determining that the stopping criterion is satisfied, the system exits the compression processing loop

In some examples, the stopping criterion includes a largest distance of the distances being less than a distance threshold.

In some examples, the distance threshold is equal to 1, and the system normalizes values of data points of the data time series, and applies the compression processing loop on the normalized values of the data points of the data time series.

In some examples, the first data point is a starting data point of the data time series, and the second data point is an ending data point of the data time series.

In some examples, the first data point or the second data point to initialize the intermediate data time series is based on an aggregate of a plurality of data points of the data time series.

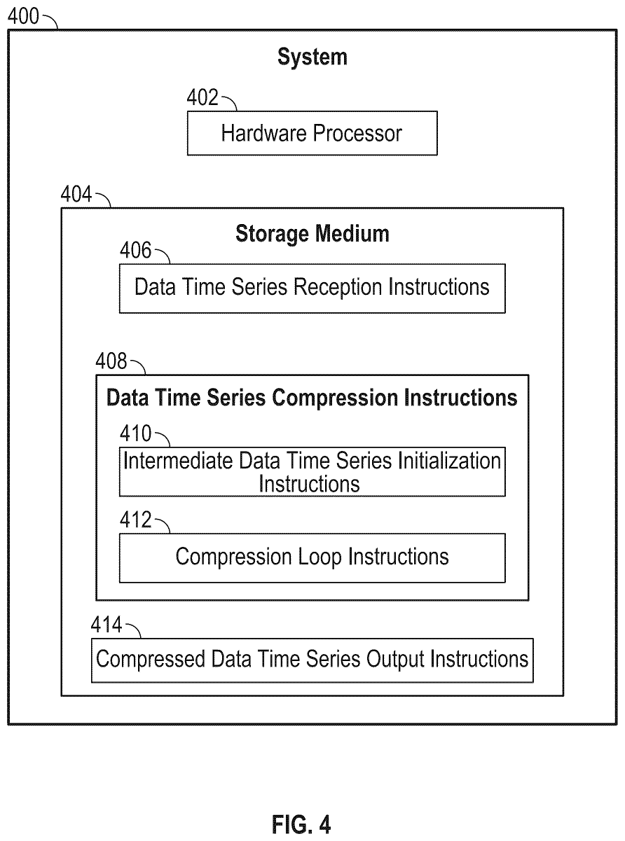

FIG. 4 is a block diagram of a system 400 according to some examples of the present disclosure. The system 400 can be implemented using one or more computers.

The system 400 includes a hardware processor 402 (or multiple hardware processors). A hardware processor can include a microprocessor, a core of a multi-core microprocessor, a microcontroller, a programmable integrated circuit, a programmable gate array, or another hardware processing circuit.

The system 400 includes a non-transitory machine-readable or computer-readable storage medium 404 storing machine-readable instructions executable on the hardware processor 402 to perform various tasks. Machine-readable instructions executable on a hardware processor can refer to the instructions executable on a single hardware processor or the instructions executable on multiple hardware processors.

The machine-readable instructions include data time series reception instructions 406 to receive a data time series, and data time series compression instructions 408 to compress the data time series.

The data time series compression instructions 408 include intermediate data time series initialization instructions 410 to initialize an intermediate data time series by adding a first data point and a second data point to the intermediate data time series.

The data time series compression instructions 408 further include compression loop instructions 412 to perform a compression processing loop including a plurality of rounds. In a respective round of the plurality of rounds, the compression processing loop selects a data point to extract from the data time series, the data point selected based on a comparison of distances between a line segment connecting data points in the intermediate data time series and corresponding data points of the data time series. In the respective round, the compression processing loop adds the extracted data point to the intermediate data time series. The plurality of rounds of the compression processing loop includes a first round and a second round performed after the first round, where a first version of the intermediate data time series in the first round includes a first quantity of data points, and a second version of the intermediate data time series in the second round includes a second quantity of data points greater than the first quantity.

The machine-readable instructions include compressed data time series output instructions 414 to output the intermediate data time series produced by the compression processing loop as a compressed data time series.

A storage medium (e.g., 404 in FIG. 4) can include any or some combination of the following: a semiconductor memory device such as a dynamic or static random access memory (a DRAM or SRAM), an erasable and programmable read-only memory (EPROM), an electrically erasable and programmable read-only memory (EEPROM), or flash memory; a magnetic disk such as a fixed, floppy and removable disk; another magnetic medium including tape; an optical medium such as a compact disk (CD) or a digital video disk (DVD); or another type of storage device. Note that the instructions discussed above can be provided on one computer-readable or machine-readable storage medium, or alternatively, can be provided on multiple computer-readable or machine-readable storage media distributed in a large system having possibly plural nodes. Such computer-readable or machine-readable storage medium or media is (are) considered to be part of an article (or article of manufacture). An article or article of manufacture can refer to any manufactured single component or multiple components. The storage medium or media can be located either in the machine running the machine-readable instructions, or located at a remote site from which machine-readable instructions can be downloaded over a network for execution.

In the present disclosure, use of the term “a,” “an,” or “the” is intended to include the plural forms as well, unless the context clearly indicates otherwise. Also, the term “includes,” “including,” “comprises,” “comprising,” “have,” or “having” when used in this disclosure specifies the presence of the stated elements, but do not preclude the presence or addition of other elements.

In the foregoing description, numerous details are set forth to provide an understanding of the subject disclosed herein. However, implementations may be practiced without some of these details. Other implementations may include modifications and variations from the details discussed above. It is intended that the appended claims cover such modifications and variations.

What is claimed is:

1. A non-transitory machine-readable storage medium comprising instructions that upon execution cause a system to:
receive a data time series;
compress the data time series, the compressing comprising:
initializing an intermediate data time series by adding a first data point and a second data point to the intermediate data time series,
in a respective round of a plurality of rounds of a compression processing loop:
selecting a data point to extract from the data time series, the data point selected based on a comparison of distances between a line segment connecting data points in the intermediate data time series and corresponding data points of the data time series, and
adding the extracted data point to the intermediate data time series; and
output the intermediate data time series produced by the compression processing loop as a compressed data time series.

2. The non-transitory machine-readable storage medium of claim 1, wherein the selecting of the data point comprises selecting the data point having a largest distance to the line segment.

3. The non-transitory machine-readable storage medium of claim 2, wherein the instructions upon execution cause the system to:
in the respective round, identifying the line segment and calculating the distances between the line segment and the corresponding data points of the data time series.

4. The non-transitory machine-readable storage medium of claim 3, wherein a distance between the line segment and a given data point of the data time series is along an axis that is perpendicular to the line segment.

5. The non-transitory machine-readable storage medium of claim 3, wherein a distance between the line segment and a given data point of the data time series is a Chebychev distance.

6. The non-transitory machine-readable storage medium of claim 3, wherein the line segment is a first line segment corresponding to a first iteration of the respective round, and wherein the instructions upon execution cause the system to, in the respective round:
identify a second line segment different from the first line segment, wherein the second line segment corresponds to a second iteration of the respective round and connects further data points in the intermediate data time series, and
calculate distances between the second line segment and further corresponding data points of the data time series.

7. The non-transitory machine-readable storage medium of claim 6, wherein the selecting of the data point to extract from the data time series is based on a comparison of first distances between the first line segment and the corresponding data points of the data time series, and second distances between the second line segment and the further corresponding data points of the data time series.

8. The non-transitory machine-readable storage medium of claim 7, wherein the selecting of the data point comprises selecting the data point having the largest distance of the first distances and the second distances.

9. The non-transitory machine-readable storage medium of claim 6, wherein the instructions upon execution cause the system to:
determine whether all distances of a given line segment of the first line segment and the second line segment is less than a distance threshold; and
based on determining that all distances of the given line segment is less than the distance threshold, exclude the given line segment from consideration in a next round of the plurality of rounds.

10. The non-transitory machine-readable storage medium of claim 1, wherein the instructions upon execution cause the system to:
in the compression processing loop, determine whether a stopping criterion is satisfied; and
in response to determining that the stopping criterion is satisfied, exit the compression processing loop.

11. The non-transitory machine-readable storage medium of claim 10, wherein the stopping criterion comprises a largest distance of the distances being less than a distance threshold.

12. The non-transitory machine-readable storage medium of claim 11, wherein the distance threshold is equal to 1, and the instructions upon execution cause the system to:
normalize values of data points of the data time series; and
apply the compression processing loop on the normalized values of the data points of the data time series.

13. The non-transitory machine-readable storage medium of claim 1, wherein the first data point is a starting data point of the data time series, and the second data point is an ending data point of the data time series.

14. The non-transitory machine-readable storage medium of claim 1, wherein the first data point or the second data point to initialize the intermediate data time series is based on an aggregate of a plurality of data points of the data time series.

15. The non-transitory machine-readable storage medium of claim 1, wherein the instructions upon execution cause the system to:
perform anomaly detection in the data time series using the compressed data time series.

16. The non-transitory machine-readable storage medium of claim 1, wherein the instructions upon execution cause the system to:
perform, using the compressed data time series, one or more of generating a visualization of the data time series, detecting plateaus in data values in the data time series, or detecting peaks or steps in the data time series.

17. A method comprising:
receiving, at a system comprising a hardware processor, a data time series;
compressing, by the system, the data time series, the compressing comprising:
initializing an intermediate data time series by adding a first data point and a second data point to the intermediate data time series,
in a respective round of a plurality of rounds of a compression processing loop:
selecting a data point to extract from the data time series, the data point selected based on a comparison of distances between a line segment connecting data points in the intermediate data time series and corresponding data points of the data time series, and
adding the extracted data point to the intermediate data time series; and
outputting, by the system, the intermediate data time series produced by the compression processing loop as a compressed data time series.

18. The method of claim 17, wherein the plurality of rounds of the compression processing loop comprises a first round and a second round performed after the first round, wherein a first version of the intermediate data time series in the first round includes a first quantity of data points, and a second version of the intermediate data time series in the second round includes a second quantity of data points greater than the first quantity.

19. A system comprising:
a hardware processor; and
a non-transitory storage medium storing instructions executable on the hardware processor to:
receive a data time series;
compress the data time series, the compressing comprising:
initializing an intermediate data time series by adding a first data point and a second data point to the intermediate data time series,
in a respective round of a plurality of rounds of a compression processing loop:
selecting a data point to extract from the data time series, the data point selected based on a comparison of distances between a line segment connecting data points in the intermediate data time series and corresponding data points of the data time series, and
adding the extracted data point to the intermediate data time series,
wherein the plurality of rounds of the compression processing loop comprises a first round and a second round, wherein a first version of the intermediate data time series in the first round includes a first quantity of data points, and a second version of the intermediate data time series in the second round includes a second quantity of data points greater than the first quantity; and
output the intermediate data time series produced by the compression processing loop as a compressed data time series.

20. The system of claim 19, wherein the selecting of the data point comprises selecting the data point having a largest distance to the line segment.
